(19) United States
(12) Patent Application Publication
(10) Pub. No.: US 2003/0227341 A1
(43) Pub. Date: Dec. 11, 2003

(54) Voltage-controlled oscillator and frequency synthesizer

(75) Inventor: Akihiro Sawada, Osaka (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/453,507

(22) Filed: Jun. 4, 2003

(30) Foreign Application Priority Data
Jun. 6, 2002 (JP) 2002-165536

(51) Int. Cl. H03B 1/00

(52) U.S. Cl. 331/177 V

(57) ABSTRACT

In a voltage-controlled oscillator, a second variable capacitor circuit is provided in a variable capacitor circuit group, in addition to a first variable capacitor circuit having a first variable capacitor whose capacitance varies continuously in accordance with a frequency control signal. The second variable capacitor circuit has several second variable capacitors whose capacitances vary continuously in accordance with the frequency control signal and switching circuits that select the second variable capacitors in accordance with frequency band control signals. The oscillation frequency is changed only with the first variable capacitor in higher oscillation frequency bands. When the oscillation frequency is in lower oscillation frequency bands, the oscillation frequency band is changed also with the second variable capacitors. Accordingly, it is possible to ensure broad oscillation frequency bands, while reducing variations in the VCO gain in the entire oscillation frequency bands to a low level.

### BACKGROUND OF THE INVENTION

The present invention relates to voltage-controlled oscillators, which are used for semiconductor integrated circuits in the radio communications field for generating local frequencies necessary for transmission/reception of radio waves, and to frequency synthesizers including such voltage-controlled oscillators. More particularly, the invention relates to expansion of the oscillation frequency range and improvement of the characteristics of the frequency synthesizers required for broadband radio frequencies used in digital TV broadcasting and the like.

FIG. 11 shows a conventional voltage-controlled oscillator. The conventional voltage-controlled oscillator shown in the figure is a circuit example presented in 2001 ISSCC Digest of Technical Paper pp. 364-365, and includes tank circuits 1 and a negative resistance generating circuit 4 that generates a negative resistance.

Each of the tank circuits 1 is formed by an inductor 2 and a variable capacitor circuit group 3. The variable capacitor circuit group 3 is formed by a first variable capacitor circuit 31 having a variable capacitor element Cᵥ₁ whose capacitance varies continuously in accordance with a voltage V_{cont} of a frequency control signal CONT, and a second variable capacitor circuit 50. The second variable capacitor circuit 50 is formed by switching transistors S₅₀ and S₅₁ controlled by two-bit frequency band control signals BIT0 and BIT1, and fixed capacitors C_{f0} and C_{f1} connected in series to the switching transistors S₅₀ and S₅₁. The capacitances of the fixed capacitors C_{f0} and C_{f1} are set to satisfy the relationship C_{f1}=2·C_{f0}. The negative resistance generating circuit 4 is formed by two cross-coupled transistors M1 and a current source transistor M2 that determines the current that passes though the circuit.

In the conventional voltage-controlled oscillator having such a configuration, a current is supplied by applying a predetermined bias to the current source transistor M2, and a pair of output terminals OUTA and OUTB start to oscillate at mutually inverted electric potentials when the value of this current exceeds a predetermined value. The oscillation frequency at this time is given by the following Equation (1):

$$f = \frac{1}{2 π} \cdot \frac{1}{\sqrt{L \cdot ( {C}_{V} + {C}_{f all} + {C}_{p} )}} \qquad ( 1 )$$

where L is the inductance of the inductor 2, Cᵥ is the capacitance of the variable capacitor element Cᵥ₁ of the first variable capacitor circuit 31, C_{f all} is the total capacitance of the fixed capacitors C_{f0} and C_{f1} additionally connected to the output terminals OUTA and OUTB by the frequency band control signals BIT0 and BIT1, and Cₚ is the total parasitic capacitance associated with the wiring and the gate capacitance and drain capacitance of the cross-coupled transistors M1.

The oscillation frequency characteristics of this conventional voltage-controlled oscillator are show in FIG. 12. When the frequency band control signals BIT0 and BIT1 are BIT [1:0]=0, 0, the fixed capacitors C_{f0} and C_{f1} are disconnected from the output terminals, so that the voltage-controlled oscillator oscillates in the highest oscillation frequency band. When the frequency band control signals BIT0 and BIT1 are BIT [1:0]=0, 1, BIT [1:0]=1, 0, and BIT [1:0]=1, 1, the total value of the fixed capacitors that are added as offset capacitors connected to the output terminals OUTA and OUTB increases, so that the voltage-controlled oscillator oscillates in a lower oscillation frequency band.

However, in the above-described conventional voltage-controlled oscillator, the oscillation frequency band is reduced. That is, the relative capacitance of the variable capacitor element Cᵥ₁ of the first variable capacitor circuit 31 to the whole capacitance decreases with an increase in the total value C_{f all} of the fixed capacitors added by the second variable capacitor circuit 50, so that when the variable capacitor element Cᵥ₁ of the first variable capacitor circuit 31 is varied over a predetermined amount, the variable bandwidth of the oscillation frequency corresponding to this capacitance variation decreases in the lower frequency bands. Consequently, it has been impossible to achieve a large oscillation frequency range for the voltage-controlled oscillator as a whole.

Furthermore, the above-described reduction in oscillation frequency range in the lower frequency bands leads to a decrease in the ratio (VCO gain) of the change in the oscillation frequency with respect to the change of the voltage V_{cont} of the frequency control signal CONT. This causes a decrease in the VCO gain in lower oscillation frequency bands with respect to the VCO gain in higher oscillation frequency bands, resulting in a problem of increased variations in the VCO gain between two oscillation frequency bands. Consequently, when a phase-locked frequency synthesizer is configured by using such a voltage-controlled oscillator, the loop characteristics of the phase-locked frequency synthesizer vary depending on the oscillation frequency band, causing variations in phase noise characteristics, spurious characteristics, lock-up time and other characteristics of the phase-locked frequency synthesizer and thus resulting in a deterioration of the characteristics.

### SUMMARY OF THE INVENTION

Therefore, with the foregoing in mind, it is an object of the present invention to ensure a sufficiently broad variable range of the oscillation frequency of a voltage-controlled oscillator according to a capacitance change even in lower oscillation frequency bands, while increasing the VCO gain in lower oscillation frequency bands to reduce variations in the VCO gain between higher and lower oscillation frequency bands to a low level.

In order to achieve the above-described object, the present invention adopts a configuration in which a variable capacitance, which varies in accordance with a change in electric potential of a frequency control signal, is changed to a larger capacitance in lower oscillation frequency bands.

Specifically, the present invention provides a voltage-controlled oscillator comprising: a tank circuit including an inductor and a variable capacitor circuit group, wherein a capacitance of the variable capacitor circuit group is selected based on N-bit frequency band control signals in such a manner that an oscillation frequency band is controlled; a negative resistance generating circuit for generating a negative resistance; and a capacitor selecting circuit that performs logical processing of the N-bit frequency band control signals and outputs a result of the processing as capacitor selecting signals, wherein the variable capacitor circuit group comprises: a first variable capacitor circuit including a first variable capacitor element whose capacitance varies continuously in accordance with a voltage of a frequency control signal; and a second variable capacitor circuit including a unit variable capacitor circuit having a switching circuit controlled by the capacitor selecting signal and a second variable capacitor element connected in series to the switching circuit and whose capacitance varies continuously in accordance with the voltage of the frequency control signal.

Additionally, in the above-described voltage-controlled oscillator according to the present invention, the second variable capacitor circuit includes N unit variable capacitor circuits and the capacitances of the second variable capacitor elements of the respective unit variable capacitor circuits are different from one another; and the capacitor selecting circuit outputs logic levels of the N-bit frequency band control signals directly as the capacitor selecting signals.

Further, in the above-described voltage-controlled oscillator according to the present invention, the second variable capacitor circuit includes 2^{N}-1 unit variable capacitor circuits; the capacitor selecting circuit outputs a number of activated capacitor selecting signals that is equal to a decimal value of the N-bit frequency band control signals; and a total capacitance of the second variable capacitor elements selected via the switching circuits by the capacitor selecting signal is set to vary for different capacitor selecting signals.

The present invention also provides a frequency synthesizer comprising: the above-described voltage-controlled oscillator; a frequency divider circuit that divides an oscillation frequency signal of the voltage-controlled oscillator at a frequency division ratio set by a frequency division ratio determining signal; a phase difference detecting circuit that detects a phase difference between a frequency signal divided by the frequency divider circuit and a reference frequency signal; a charge pump circuit that outputs an electric charge corresponding to an output of the phase difference detecting circuit; and a low-pass filter that passes only low frequency components of an output of the charge pump circuit and outputs these components as the frequency control signal to the voltage-controlled oscillator.

The present invention also provides a voltage-controlled oscillator comprising: a tank circuit including an inductor and a variable capacitor circuit group, wherein a capacitance of the variable capacitor circuit group is selected based on N-bit frequency band control signals in such a manner that an oscillation frequency band is controlled; a negative resistance generating circuit for generating a negative resistance; and a capacitor selecting circuit that performs logical processing of the N-bit frequency band control signals and outputs a result of the processing as capacitor selecting signals, wherein the variable capacitor circuit group comprises: a first variable capacitor circuit including a first variable capacitor element whose capacitance varies continuously in accordance with a voltage of a frequency control signal; a second variable capacitor circuit including a unit variable capacitor circuit having a first switching circuit controlled by the capacitor selecting signal and a second variable capacitor element connected in series to the first switching circuit and whose capacitance varies continuously in accordance with the voltage of the frequency control signal; and a third variable capacitor circuit including a unit fixed capacitor circuit having a second switching circuit controlled by the capacitor selecting signal and a fixed capacitor element connected to an analog ground wire via the second switching circuit.

Further, in the above-described voltage-controlled oscillator according to the present invention, the second variable capacitor circuit includes N unit variable capacitor circuits and the capacitances of the second variable capacitor elements of the respective unit variable capacitor circuits are different from one another; the third variable capacitor circuit includes N unit fixed capacitor circuits and the capacitances of the unit fixed capacitor elements of the respective unit fixed capacitor circuits are different from one another; and the capacitor selecting circuit outputs logic levels of the N-bit frequency band control signals directly as the capacitor selecting signals.

Additionally, in the above-described voltage-controlled oscillator according to the present invention, the second variable capacitor circuit includes 2^{N}-1 unit variable capacitor circuits; the third variable capacitor circuit includes 2^{N}-1 unit fixed capacitor circuits; the capacitor selecting circuit outputs a number of activated capacitor selecting signals that is equal to a decimal value of the N-bit frequency band control signals; a total capacitance of the second variable capacitor elements selected via the first switching circuits by the capacitor selecting signal is set to vary for different capacitor selecting signals; and a total capacitance of the fixed capacitor elements selected via the second switching circuits by the capacitor selecting signal is set to vary for different capacitor selecting signals.

Furthermore, the present invention provides a frequency synthesizer comprising: the above-described voltage-controlled oscillator; a frequency divider circuit that divides an oscillation frequency signal of the voltage-controlled oscillator at a frequency division ratio set by a frequency division ratio determining signal; a phase difference detecting circuit that detects a phase difference between a frequency signal divided by the frequency divider circuit and a reference frequency signal; a charge pump circuit that outputs an electric charge corresponding to an output of the phase difference detecting circuit; and a low-pass filter that passes only low frequency components of an output of the charge pump circuit and outputs these components as the frequency control signal to the voltage-controlled oscillator.

As described above, in the voltage-controlled oscillator according to the present invention, the capacitance is changed only with a first variable capacitor circuit having a first variable capacitor element in the higher oscillation frequency bands. In the lower oscillation frequency bands, on the other hand, the capacitance is changed also with a second variable capacitor circuit having a second variable capacitor element, as well as with the first variable capacitor circuit. The oscillation frequency band can therefore be changed with a larger capacitance in the lower oscillation frequency bands than in the higher oscillation frequency bands, so that a sufficiently broad variable range of oscillation frequencies can be ensured, which in turn increases the VCO gain in the lower oscillation frequency bands, thereby reducing variations in the VCO gain between higher and lower oscillation frequency bands to a low level.

Moreover, the voltage-controlled oscillator according to the present invention further includes a third variable capacitor circuit having a fixed capacitor element, in addition to the second variable capacitor circuit having the second variable capacitor element. Therefore, it can appropriately adjust the relationship between offset capacitance components and variable capacitance components in lower oscillation frequency bands, thereby reducing variations in the VCO gain between higher and lower oscillation frequency bands to an even lower level.

Furthermore, the frequency synthesizer according to the present invention is configured by using the above-described voltage-controlled oscillator that has broad variable oscillation frequency bands and smaller variations in the VCO gain between higher and lower oscillation frequency bands. Therefore, its loop characteristics are substantially the same in higher and lower oscillation frequency bands, so that it is possible to obtain a high-performance frequency synthesizer with smaller variations in phase noise characteristics, spurious characteristics, lock-up time and the like.

### BRIEF DESCRIPTION OF THE DRAWINGS

FIG. 1 is a diagram showing a circuit configuration of a voltage-controlled oscillator according to Embodiment 1 of the present invention.

FIG. 2 is a graph showing the oscillation frequency characteristics of the same voltage-controlled oscillator.

FIG. 3 is a diagram showing a circuit configuration of a voltage-controlled oscillator according to Embodiment 2 of the present invention.

FIG. 4 is a graph showing the oscillation frequency characteristics of the same voltage-controlled oscillator.

FIG. 5 is a diagram showing a circuit configuration of a voltage-controlled oscillator according to Embodiment 3 of the present invention.

FIG. 6 is a graph showing the oscillation frequency characteristics of the same voltage-controlled oscillator.

FIG. 7 is a diagram showing a circuit configuration of a voltage-controlled oscillator according to Embodiment 4 of the present invention.

FIG. 8 is a graph showing the oscillation frequency characteristics of the same voltage-controlled oscillator.

FIG. 9 is a graph showing results of comparison of the VCO gain characteristics of the voltage-controlled oscillators according to Embodiments 1 and 3 of the present invention with the VCO gain characteristics of a conventional voltage-controlled oscillator.

FIG. 10 is a diagram showing a block configuration of a frequency synthesizer according to Embodiment 5 of the present invention.

FIG. 11 is a diagram showing a circuit configuration of a conventional voltage-controlled oscillator.

FIG. 12 is a graph showing the oscillation frequency characteristics of the same conventional voltage-controlled oscillator.

### DETAILED DESCRIPTION OF THE INVENTION

Hereinbelow, preferred embodiments of the present invention are described with reference to the appended drawings.

### Embodiment 1

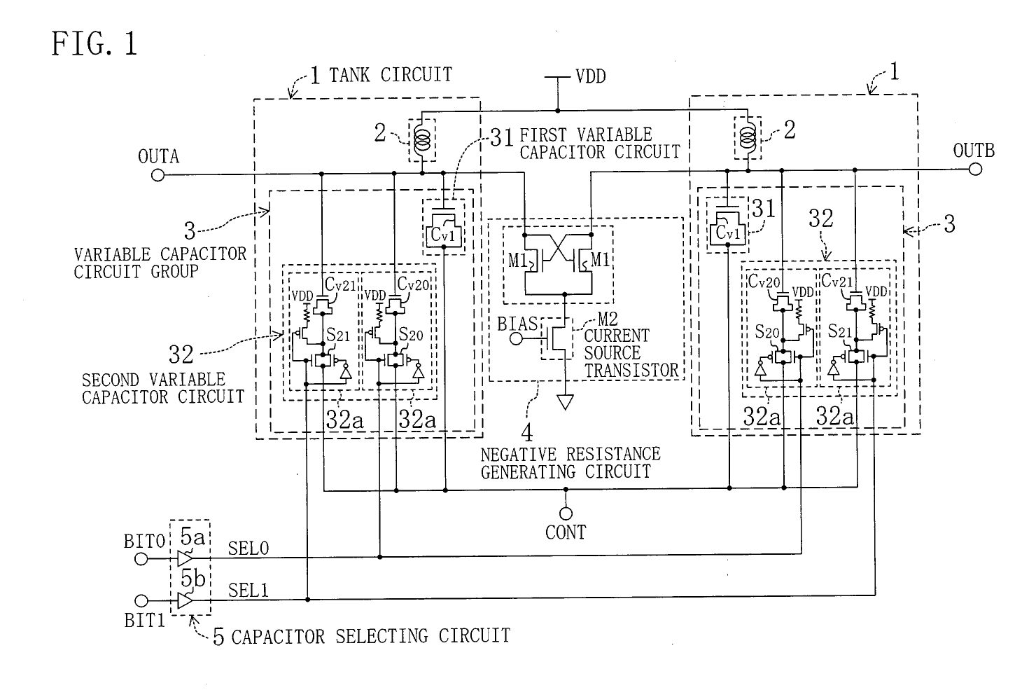

FIG. 1 shows a circuit configuration of a voltage-controlled oscillator according to Embodiment 1 of the present invention.

The voltage-controlled oscillator shown in the figure is formed by tank circuits 1 that determine the oscillation frequency, a negative resistance generating circuit 4 and a capacitor selecting circuit 5. The negative resistance generating circuit 4 generates a negative resistance to compensate any loss of the tank circuits 1, thereby enabling oscillation.

Each of the tank circuits 1 is formed by an inductor 2 and a variable capacitor circuit group 3. The negative resistance generating circuit 4 is formed by two cross-coupled transistors M1 and a current source transistor M2. The capacitor selecting circuit 5 performs logical processing of N-bit (two-bit, in the figure) frequency band control signals BIT0 and BIT1, and outputs the result of the processing as capacitor selecting signals SEL0 and SEL1. Specifically, in this embodiment, the capacitor selecting circuit 5 has buffers 5a and 5b that receive the frequency band control signals BIT0 and BIT1, respectively, and outputs the logic levels of the received frequency band control signals BIT0 and BIT1 from the buffers 5a and 5b directly as the capacitor selecting signals SEL0 and SEL1.

The variable capacitor circuit group 3 of the tank circuit 1 is formed by a first variable capacitor circuit 31 and a second variable capacitor circuit 32. The first variable capacitor circuit 31 has a first variable capacitor element Cᵥ₁ whose capacitance varies continuously in accordance with a voltage V_{cont} of the frequency control signal CONT. The second variable capacitor circuit 32 includes switching circuits S₂₀ and S₂₁ controlled by the capacitor selecting signals SEL0 and SEL1, and N (N=2 in this embodiment) unit variable capacitor circuits 32a that are formed by second variable capacitor elements Cᵥ₂₀ and Cᵥ₂₁ connected in series to the switching circuits S₂₀ and S₂₁, respectively. Like the first variable capacitor element Cᵥ₁, also the capacitances of the second variable capacitor elements Cᵥ₂₀ and Cᵥ₂₁ vary continuously in accordance with a voltage V_{cont} of the frequency control signal CONT.

Specifically, the first variable capacitor element Cᵥ₁ of the first variable capacitor circuit 31 can be realized by connecting an accumulation-mode MOS varactor between the frequency control signal CONT and the output terminals OUTA and OUTB. The switching circuits S₂₀ and S₂₁ of the second variable capacitor circuit 32 are formed by: CMOS switching circuits having an NMOS transistor whose gate is connected to the frequency band control signal BIT0 or BIT1 and a PMOS transistor whose gate is connected to the inverted signal of the frequency band control signal BIT0 or BIT1; and a PMOS transistor and a resistor for fixing the electric potential at the node that leads to the second variable capacitor elements Cᵥ₂₀ and Cᵥ₂₁ when the CMOS switching circuit is OFF. The second variable capacitor elements Cᵥ₂₀ and Cᵥ₂₁ are formed by accumulation-mode varactors connected between the CMOS switching circuits and the output terminals OUTA and OUTB.

Here, the capacitances of the second variable capacitor elements Cᵥ₂₀ and Cᵥ₂₁ (hereinafter, denoted by the same reference symbols as the capacitor elements) are different from one another, and are set to Cᵥ₂₀<Cᵥ₂₁.

Next, the operation of the voltage-controlled oscillator shown in FIG. 1 is described. When a predetermined constant voltage is applied to the gate of the current source transistor M2, a current corresponding to that voltage is passed through the current source transistor M2 and the cross-coupled transistors M1. When this current exceeds a predetermined current value, an oscillation having mutually inverted electric potentials at the output terminals OUTA and OUTB is generated.

The oscillation frequency at this time is given by the following Equation (2):

$$f = \frac{1}{2 π} \cdot \frac{1}{\sqrt{L \cdot ( {C}_{V1} + {C}_{V2 all} + {C}_{p} )}} \qquad ( 2 )$$

where L is the inductance of the inductor 2, Cᵥ₁ is the capacitance of the first variable capacitor element Cᵥ₁, C_{v2 all} an is the total capacitance of the second variable capacitor elements Cᵥ₂₀ and Cᵥ₂₁ additionally connected to the output terminals OUTA and OUTB by the second variable capacitor circuit 32, and Cₚ is the total parasitic capacitance at the output terminals OUTA and OUTB due to the wiring and the gate capacitance and drain capacitance of the cross-coupled transistors M1.

When the frequency band control signals BIT0 and BIT1 are BIT [1:0]=0, 0, the capacitor selecting signals SEL0 and SEL1 are SEL [1:0]=0, 0. At this time, the second variable capacitor elements Cᵥ₂₀ and Cᵥ₂₁ are not selected, and C_{v2 all}=0. Accordingly, only the capacitance of the first variable capacitor element Cᵥ₁ serves as the variable capacitance that determines the oscillation frequency.

Likewise, only the second variable capacitor element Cᵥ₂₀ is selected when the frequency band control signals BIT0 and BIT1 are BIT [1:0]=0, 1; only the second variable capacitor element Cᵥ₂₁ is selected when BIT [1:0]=1, 0; and both of the second variable capacitor elements Cᵥ₂₀ and Cᵥ₂₁ are selected when BIT [1:0]=1, 1, with the variable capacitances in these cases being Cᵥ₁+Cᵥ₂₀, Cᵥ₁+Cᵥ₂₁ (>Cᵥ₁+Cᵥ₂₀) and Cᵥ₁+Cᵥ₂₀+Cᵥ₂₁ (>Cᵥ₁+Cᵥ₂₁), respectively. As is clear from this, it is possible to realize a voltage-controlled oscillator in which the variable capacitance used for changing the oscillation frequency band is increased as the bit value of the frequency band control signals BIT0 and BIT1 increases.

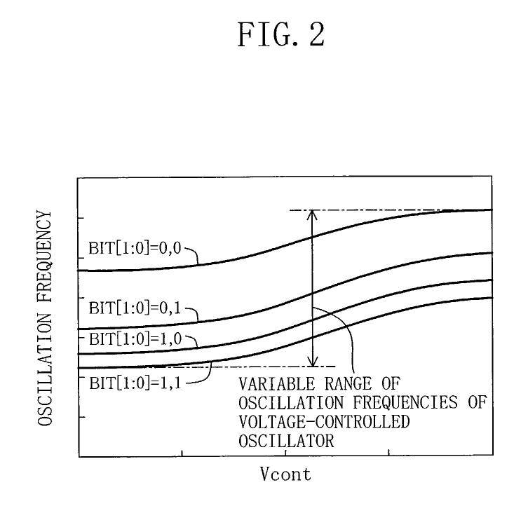

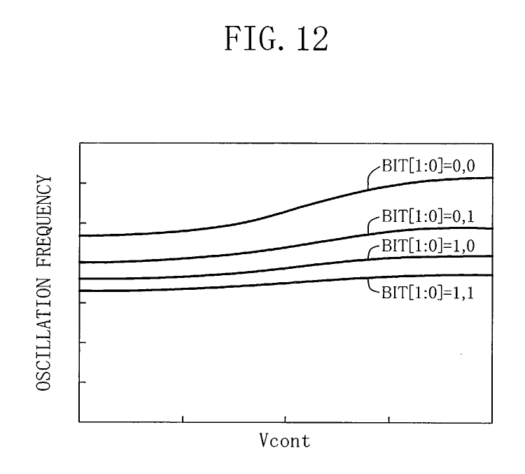

FIG. 2 shows results of simulating the relationship between the oscillation frequency and the voltage V_{cont} of the frequency control signal CONT of the voltage-controlled oscillator according to this embodiment. Here, in the voltage-controlled oscillator according to this embodiment, the capacitance is changed with variable capacitors having increasingly larger variable ranges in lower oscillation frequency bands, so that the lower oscillation frequency bands are not reduced as in the conventional voltage-controlled oscillator shown in FIG. 12. Instead, the lower oscillation frequency bands are expanded, making it possible to achieve a variable range of oscillation frequencies that is broader than that of the conventional voltage-controlled oscillator. Moreover, since the variable range of oscillation frequencies is expanded in the lower oscillation frequency bands, variations in the VCO gain between higher and lower oscillation frequency bands are reduced.

### Embodiment 2

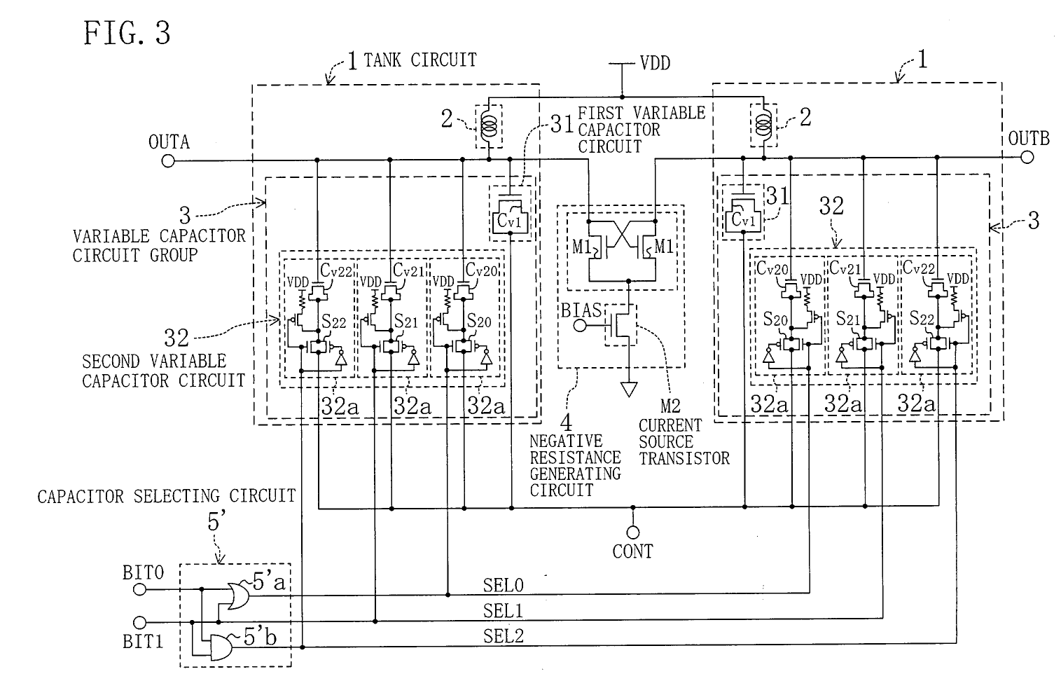

FIG. 3 shows a circuit configuration of a voltage-controlled oscillator according to Embodiment 2 of the present invention.

The voltage-controlled oscillator shown in the figure differs from Embodiment 1 shown in FIG. 1 in that one unit variable capacitor circuit 32a has been added in the second variable capacitor circuit 32, i.e., the second variable capacitor circuit 32 is formed by three (2^{N}-1, N=2) unit variable capacitor circuits 32a. Also the added unit variable capacitor circuit 32a is formed by a switching circuit S₂₂ and a second variable capacitor element Cᵥ₂₂ connected in series to the switching circuit S₂₂, like the other unit variable capacitor circuits 32a.

A capacitor selecting circuit 5′ outputs a number of the capacitor selecting signals SEL0, SEL1 and SEL2 that is equal to the number (three) of unit variable capacitor circuits 32a of the second variable capacitor circuit 32. The capacitor selecting circuit 5′ contains an OR circuit 5′a and an AND circuit 5′b. The OR circuit 5′a and the AND circuit 5′b receive the frequency band control signals BIT0 and BIT1 and output the capacitor selecting signals SEL0 and SEL2, respectively. The logic level of the frequency band control signal BIT1 is taken directly as the capacitor selecting signal SEL1.

That is, the capacitor selecting circuit 5′ is configured so as to inactivate (set to 0 level) all the capacitor selecting signals SEL0, SEL1 and SEL2 when the frequency band control signals are BIT [1:0]=0, 0 (0 in decimal value), to activate (set to 1 level) only the one capacitor selecting signal SEL0 when BIT [1:0]=0, 1 (1 in decimal value), to activate the two capacitor selecting signals SEL0 and SEL1 when BIT [1:0]=1, 0 (2 in decimal value), and to activate all the (three) capacitor selecting signals SEL0, SEL1 and SEL2 when BIT [1:0]=1, 1 (3 in decimal value).

Accordingly, the total capacitances when the frequency band control signals are BIT [1:0]=0, 0, BIT [1:0]=0, 1, BIT [1:0]=1, 0, and BIT [1:0]=1, 1 are Cᵥ₁, Cᵥ₁+Cᵥ₂₀, Cᵥ₁+Cᵥ₂₀+Cᵥ₂₁, and Cᵥ₁+Cᵥ₂₀+C₂₁+C₂₂, respectively, with the capacitances increasing in this order. The variable capacitance is the same as that of the voltage-controlled oscillator according to Embodiment 1 shown in FIG. 1 when the frequency band control signals are BIT [1:0]=0, 0 and BIT [1:0]=0, 1. However, when the frequency band control signals are BIT [1:0]=1, 0 and BIT [1:0]=1, 1, the variable capacitance is larger than that of the voltage-controlled oscillator according to Embodiment 1. That is, the variable capacitance is larger than that of Embodiment 1 by the capacitance of the variable capacitor element Cᵥ₂₀ when the frequency band control signals are BIT [1:0]=1, 0, and by the capacitance of the variable capacitor Cᵥ₂₂ device when they are BIT [1:0]=1, 1.

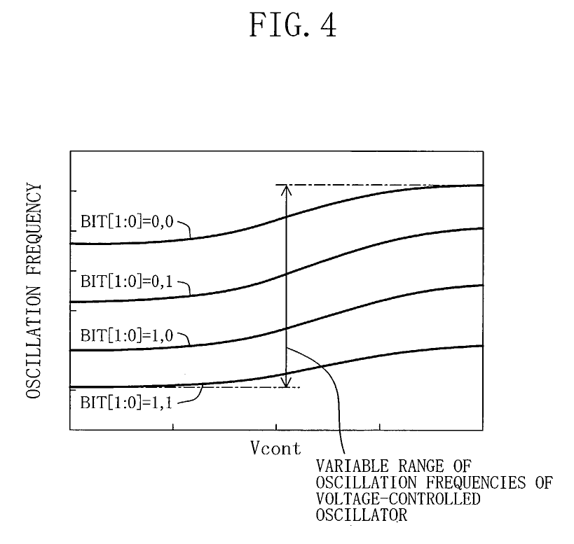

Therefore, as is clear from results of simulating the oscillation frequency characteristics of the voltage-controlled oscillator according to Embodiment 2 shown in FIG. 4, the lower oscillation frequency bands are more expanded than those of Embodiment 2 shown in FIG. 2, expanding the variable range of the oscillation frequency of the voltage-controlled oscillator further.

### Embodiment 3

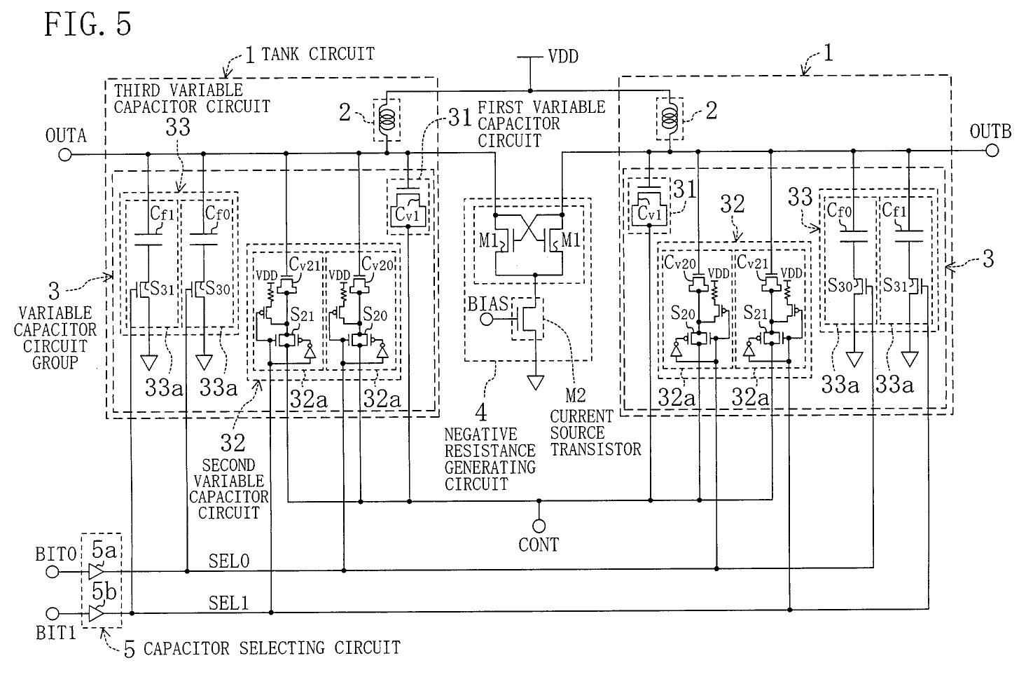

FIG. 5 shows a circuit configuration of a voltage-controlled oscillator according to Embodiment 3 of the present invention. The voltage-controlled oscillator according to this embodiment differs from the voltage-controlled oscillator according to Embodiment 1 shown in FIG. 1 in that a third variable capacitor circuit 33 is provided in the third variable capacitor circuit group 3, in addition to the first and second variable capacitor circuits 31 and 32. The first variable capacitor circuit 31 has the first variable capacitor element Cᵥ₁ whose capacitance varies continuously in accordance with a voltage V_{cont} of the frequency control signal CONT. The second variable capacitor circuit 32 has N (=2) switching circuits (first switching circuits) S₂₀ and S₂₁, and N (=2) second variable capacitor elements Cᵥ₂₀ and Cᵥ₂₁ connected in series to the switching circuits S₂₀ and S₂₁. The capacitances of the variable capacitor elements Cᵥ₂₀ and Cᵥ₂₁ are different from one another, and are set to satisfy the relationship Cᵥ₂₀<Cᵥ₂₁.

The third variable capacitor circuit 33 includes N (=2) unit fixed capacitor circuits 33a. The unit fixed capacitor circuits 33a each have a switching circuit (second switching circuit) S₃₀ or S₃₁ controlled by the N (=2) bit capacitor selecting signals SEL0 and SEL1, and a fixed capacitor element C_{f0} or C_{f1} connected to an analog ground wire, via the switching circuits S₃₀ and S₃₁. The capacitances of the fixed capacitor elements C_{f0} and C_{f1} are set to be different from one another. The internal configuration of the capacitor selecting circuit 5 is identical to that of the capacitor selecting circuit 5 according to the voltage-controlled oscillator of Embodiment 1 shown in FIG. 1.

In the voltage-controlled oscillator according to this embodiment, the oscillation frequency band is set by the combination of the fixed capacitor elements C_{f0} and C_{f1} with the variable capacitor elements Cᵥ₂₀ and Cᵥ₂₁. In this case, the oscillation frequency is given by the following Equation (3):

$$f = \frac{1}{2 π} \cdot \frac{1}{\sqrt{L \cdot ( {C}_{V1} + {C}_{V2 all} + {C}_{f all} + {C}_{p} )}} \qquad ( 3 )$$

where C_{f all} is the total capacitance of the fixed capacitor element C_{f0} and C_{f1} additionally connected to the output terminals OUTA and OUTB.

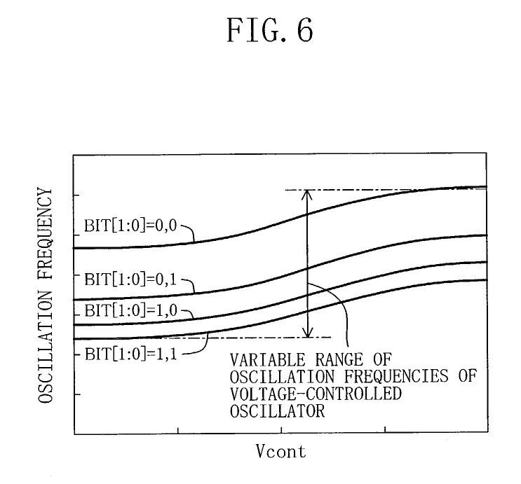

In this embodiment, it is therefore possible to adjust the relationship between the capacitance Cᵥ₁+C_{v2 all} serving as a variable capacitance component and the capacitance C_{f all}+Cₚ serving as a fixed capacitance component. Accordingly, as is clear from results of simulating the oscillation frequency characteristics of the voltage-controlled oscillator according to this embodiment shown in FIG. 6, it is possible to expand the oscillation frequency range in lower oscillation frequency bands, while further reducing variations in the VCO gain between higher and lower oscillation frequency bands to a lower level than in the voltage-controlled oscillator shown in FIG. 1.

### Embodiment 4

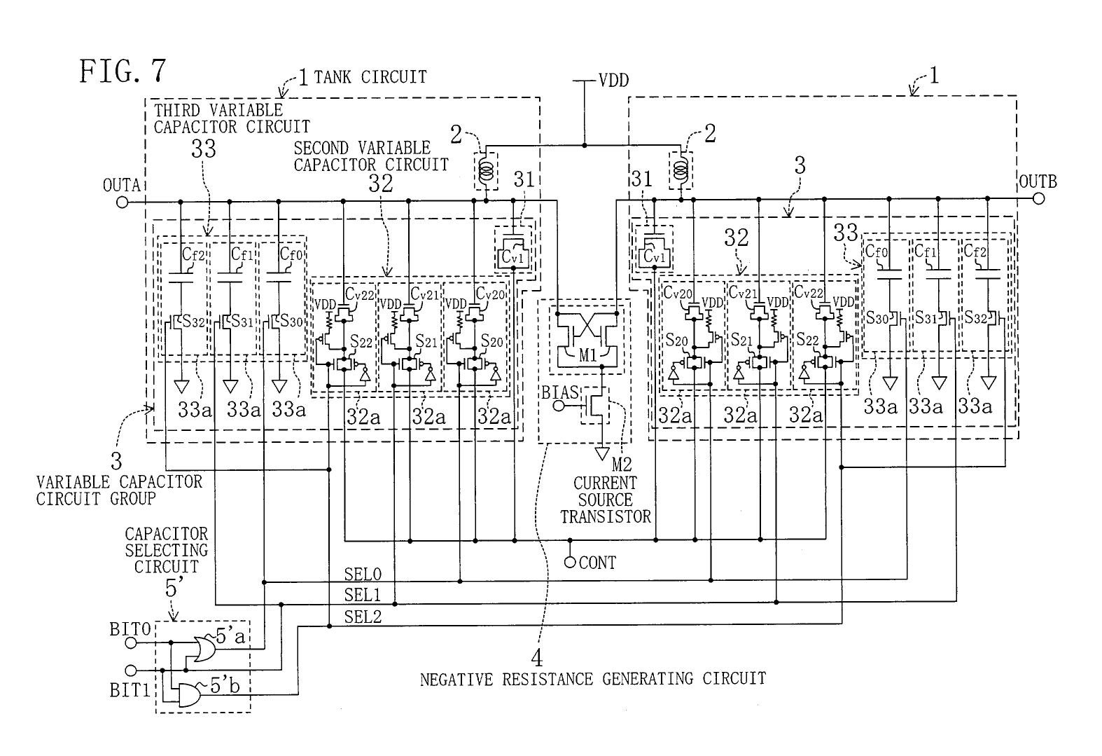

FIG. 7 shows a circuit configuration of a voltage-controlled oscillator according to Embodiment 4 of the present invention.

In the voltage-controlled oscillator according to this embodiment, the second variable capacitor circuit 32 is formed by three (2^{N}-1, N=2) unit variable capacitor circuits 32a, and the third variable capacitor circuit 33 is formed by three (2^{N}-1, N=2) unit fixed capacitor circuits 33a , each including fixed capacitor elements C_{f0}, Cₙ and C_{f2} having capacitances different from one another. Additionally, like the voltage-controlled oscillator according to Embodiment 2 shown in FIG. 3, the capacitor selecting circuit 5′ has a configuration identical to that of the capacitor selecting circuit 5′, which outputs three (2^{N}-1, N=2) capacitor selecting signals SEL0 to SEL2.

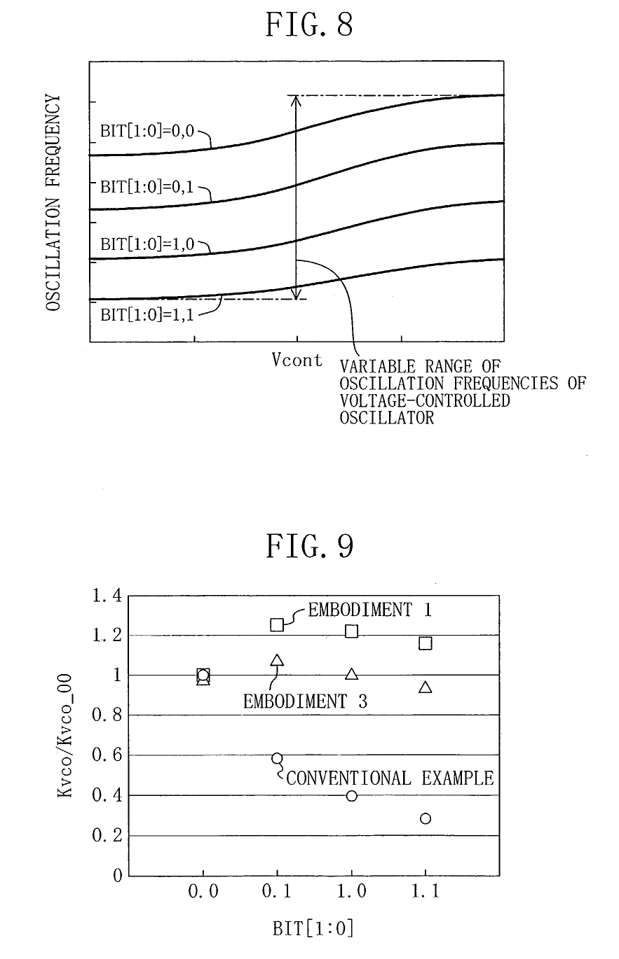

The voltage-controlled oscillator according to this embodiment can therefore have a larger variable capacitance as a variable capacitance component in the lower oscillation frequency bands. Accordingly, as is clear from results of simulating the oscillation frequency characteristics of the voltage-controlled oscillator according to this embodiment shown in FIG. 8, the lower oscillation frequency bands are more expanded, making it possible to achieve a broader variable range of oscillation frequencies of the voltage-controlled oscillator as a whole, as compared with Embodiment 3 shown in FIG. 5. At the same time, like the above-described Embodiment 3, it is possible to adjust the relationship between the variable capacitance components and the fixed capacitance components. Accordingly, it is possible to effectively reduce variations in the VCO gain between higher and lower oscillation frequency bands to a low level.

FIG. 9 shows the maximum values of the VCO gain in the oscillation frequency bands of the voltage-controlled oscillators of the above-described Embodiments 1 and 3 and the conventional example. It should be noted that the figure shows the maximum values normalized to the maximum values of the VCO gain obtained when the frequency band control signals are BIT [1:0]=0, 0. As is evident from the figure, variations in the VCO gain decrease in the following order: conventional example shown in FIG. 12 >Embodiment 1>Embodiment 3.

Although the frequency band control signals BIT1 and BIT2 were composed of two bits in the above descriptions of the voltage-controlled oscillators according to Embodiments 1 to 4, the present invention is not limited thereto, and they may of course be composed of one bit or three or more bits.

Although the negative resistance generating circuit 4 was formed by the NMOS cross-coupled transistors M1 and the NMOS current source transistor M2, it may of course be formed by, for example, PMOS cross-coupled transistors or cross-coupled transistors using both PMOS and NMOS transistors and a PMOS current source transistor. Alternatively, it may use bipolar transistors. In addition, it is not necessary that the negative resistance generating circuit 4 be formed by cross-coupled transistors and a current source transistor.

Further, although accumulation-mode MOS varactors were used as the variable capacitor elements Cᵥ₁, Cᵥ₂₀, Cᵥ₂₁ and Cᵥ₂₂, any other device whose capacitance varies in accordance with a voltage difference between two terminals, for example, NMOS transistors, PMOS transistors or PN junctions may be used.

### Embodiment 5

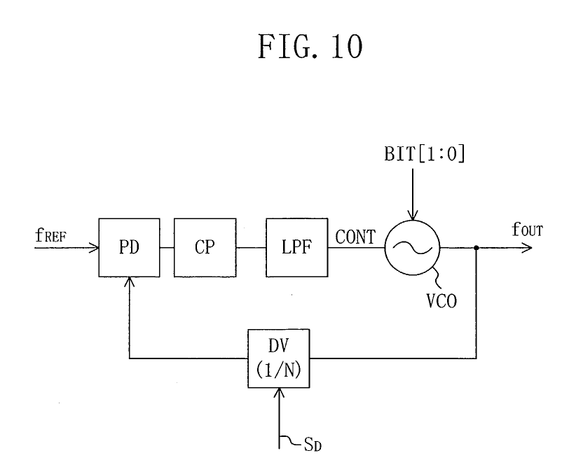

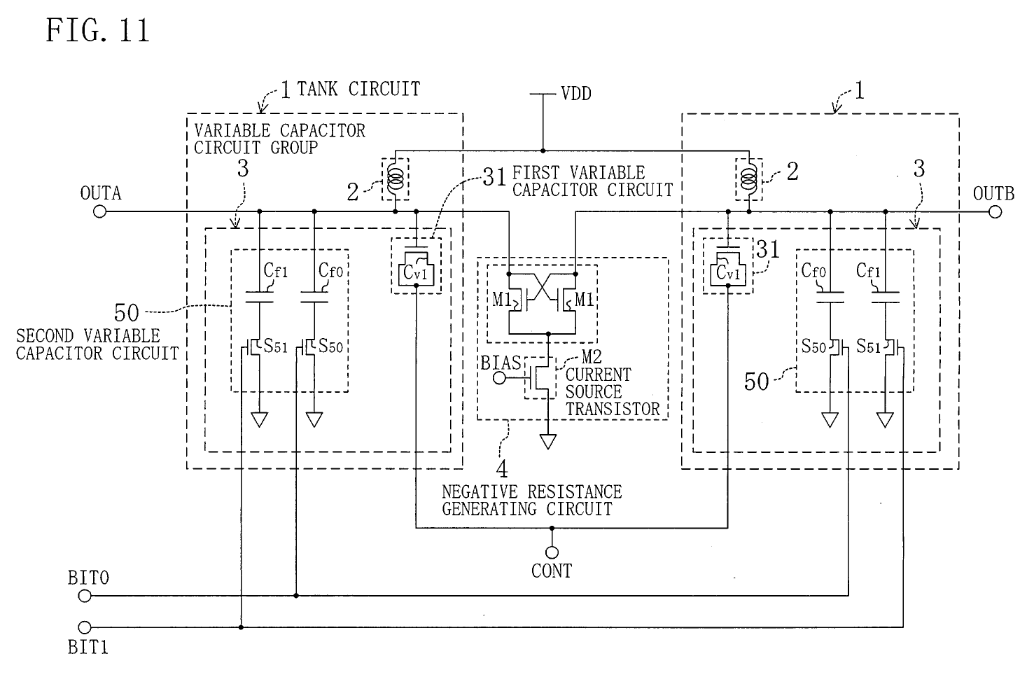

FIG. 10 shows a block diagram of a frequency synthesizer using the voltage-controlled oscillator according to the present invention.

In the frequency synthesizer shown in the figure, VCO denotes the voltage-controlled oscillators according to the above-described Embodiments 1 to 4. DV denotes a frequency divider circuit, whose frequency division ratio 1/N is set by a frequency division ratio determining signal S_{D}, and an oscillation frequency signal f_{OUT} of the voltage-controlled oscillator VCO is divided at the set frequency division ratio 1/N. PD denotes a phase difference detecting circuit, which detects a phase difference between the oscillation frequency signal divided by the frequency divider circuit DV and a reference frequency signal f_{REF}. CP denotes a charge pump circuit, which outputs an electric charge corresponding to an output of the phase difference detecting circuit PD. LPF denotes a low-pass filter, which passes only low frequency components of the output of the charge pump circuit CP and outputs these components as the frequency control signal CONT to the voltage-controlled oscillator VCO.

As described above, in the frequency synthesizer according to this embodiment, the voltage-controlled oscillator VCO has a very broad oscillation frequency band, so that it is possible to configure a frequency synthesizer that covers this broad frequency band.

Moreover, since it uses the voltage-controlled oscillator VCO in which variations in the VCO gain between higher and lower frequency, bands are small, it is possible to reduce variations in the loop characteristics of the frequency synthesizer itself, thereby configuring a high-performance frequency synthesizer with smaller variations in phase noise characteristics, reference spurious characteristics, lock-up time and the like.

The invention may be embodied in other forms without departing from the spirit or essential characteristics thereof The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A voltage-controlled oscillator comprising:
a tank circuit including an inductor and a variable capacitor circuit group, wherein a capacitance of the variable capacitor circuit group is selected based on N-bit frequency band control signals in such a manner that an oscillation frequency band is controlled;
a negative resistance generating circuit for generating a negative resistance; and
a capacitor selecting circuit that performs logical processing of the N-bit frequency band control signals and outputs a result of the processing as capacitor selecting signals, wherein
the variable capacitor circuit group comprises:
a first variable capacitor circuit including a first variable capacitor element whose capacitance varies continuously in accordance with a voltage of a frequency control signal; and
a second variable capacitor circuit including a unit variable capacitor circuit having a switching circuit controlled by the capacitor selecting signal and a second variable capacitor element connected in series to the switching circuit and whose capacitance varies continuously in accordance with the voltage of the frequency control signal.

2. The voltage-controlled oscillator according to claim 1,
wherein the second variable capacitor circuit includes N unit variable capacitor circuits and the capacitances of the second variable capacitor elements of the respective unit variable capacitor circuits are different from one another; and
wherein the capacitor selecting circuit outputs logic levels of the N-bit frequency band control signals directly as the capacitor selecting signals.

3. The voltage-controlled oscillator according to claim 1,
wherein the second variable capacitor circuit includes 2^{N}-1 unit variable capacitor circuits;
wherein the capacitor selecting circuit outputs a number of activated capacitor selecting signals that is equal to a decimal value of the N-bit frequency band control signals; and
wherein a total capacitance of the second variable capacitor elements selected via the switching circuits by the capacitor selecting signal is set to vary for different capacitor selecting signals.

4. A frequency synthesizer comprising:
the voltage-controlled oscillator according to claim 1;
a frequency divider circuit that divides an oscillation frequency signal of the voltage-controlled oscillator at a frequency division ratio set by a frequency division ratio determining signal;
a phase difference detecting circuit that detects a phase difference between a frequency signal divided by the frequency divider circuit and a reference frequency signal;
a charge pump circuit that outputs an electric charge corresponding to an output of the phase difference detecting circuit; and
a low-pass filter that passes only low frequency components of an output of the charge pump circuit and outputs these components as the frequency control signal to the voltage-controlled oscillator.

5. A voltage-controlled oscillator comprising:
a tank circuit including an inductor and a variable capacitor circuit group, wherein a capacitance of the variable capacitor circuit group is selected based on N-bit frequency band control signals in such a manner that an oscillation frequency band is controlled;
a negative resistance generating circuit for generating a negative resistance; and
a capacitor selecting circuit that performs logical processing of the N-bit frequency band control signals and outputs a result of the processing as capacitor selecting signals, wherein
the variable capacitor circuit group comprises:
a first variable capacitor circuit including a first variable capacitor element whose capacitance varies continuously in accordance with a voltage of a frequency control signal;
a second variable capacitor circuit including a unit variable capacitor circuit having a first switching circuit controlled by the capacitor selecting signal and a second variable capacitor element connected in series to the first switching circuit and whose capacitance varies continuously in accordance with the voltage of the frequency control signal; and
a third variable capacitor circuit including a unit fixed capacitor circuit having a second switching circuit controlled by the capacitor selecting signal and a fixed capacitor element connected to an analog ground wire via the second switching circuit.

6. The voltage-controlled oscillator according to claim 5,
wherein the second variable capacitor circuit includes N unit variable capacitor circuits and the capacitances of the second variable capacitor elements of the respective unit variable capacitor circuits are different from one another;
wherein the third variable capacitor circuit includes N unit fixed capacitor circuits and the capacitances of the unit fixed capacitor elements of the respective unit fixed capacitor circuits are different from one another; and
wherein the capacitor selecting circuit outputs logic levels of the N-bit frequency band control signals directly as the capacitor selecting signals.

7. The voltage-controlled oscillator according to claim 5,
wherein the second variable capacitor circuit includes 2^{N}-1 unit variable capacitor circuits;
wherein the third variable capacitor circuit includes 2^{N}-1 unit fixed capacitor circuits;
wherein the capacitor selecting circuit outputs a number of activated capacitor selecting signals that is equal to a decimal value of the N-bit frequency band control signals;
wherein a total capacitance of the second variable capacitor elements selected via the first switching circuits by the capacitor selecting signal is set to vary for different capacitor selecting signals; and
wherein a total capacitance of the fixed capacitor elements selected via the second switching circuits by the capacitor selecting signal is set to vary for different capacitor selecting signals.

8. A frequency synthesizer comprising:
the voltage-controlled oscillator according to claim 5;
a frequency divider circuit that divides an oscillation frequency signal of the voltage-controlled oscillator at a frequency division ratio set by a frequency division ratio determining signal;
a phase difference detecting circuit that detects a phase difference between a frequency signal divided by the frequency divider circuit and a reference frequency signal;
a charge pump circuit that outputs an electric charge corresponding to an output of the phase difference detecting circuit; and
a low-pass filter that passes only low frequency components of an output of the charge pump circuit and outputs these components as the frequency control signal to the voltage-controlled oscillator.
